(19) United States
(12) Patent Application Publication
(10) Pub. No.: US 2026/0075782 A1
(43) Pub. Date: Mar. 12, 2026

(54) ELECTRONIC DEVICE AND METHOD OF COOLING THEREOF

(71) Applicant: TRUMPF HUETTINGER SP. Z O. O., Zielonka (PL)

(72) Inventors: Michal Balcerak, Marki (PL); Andrzej Klimczak, Warsaw (PL)

(21) Appl. No.: 19/392,185

(22) Filed: Nov. 18, 2025

Related U.S. Application Data
(63) Continuation of application No. PCT/EP2024/063826, filed on May 17, 2024.

(30) Foreign Application Priority Data
May 19, 2023 (EP) 23460018.7

(51) Int. Cl. H05K 7/20; H05K 5/06

(52) U.S. Cl. CPC H05K 7/20927; H05K 5/067; H05K 5/068; H05K 7/20236; H05K 7/20272

(57) ABSTRACT

An electronic device for a high power, high voltage pulsed power supply for plasma processing for biasing a substrate in a plasma process, the electronic device including a plurality of electrical components configured to generate heat when the device is in use and a container. At least a part of the plurality of electrical components are placed in the container. The electronic device further includes an electrically insulating heat transfer liquid, filled within the container and having direct contact to the plurality of electrical components and configured to transport heat away from the plurality of electrical components. The electrically insulating heat transfer liquid is enclosed in a hermetical closed volume, the hermetical closed volume being arranged at least partly inside the container and kept in a predetermined regulated pressure range.

### CROSS REFERENCE TO RELATED APPLICATIONS

This application is a continuation of International Application No. PCT/EP2024/063826 (WO 2024/240702 A1), filed on May 17, 2024, and claims benefit to European Patent Application No. EP 23460018.7, filed on May 19, 2023. The aforementioned applications are hereby incorporated by reference herein.

### FIELD

The invention relates to an electronic device comprising a plurality of electrical components generating heat for, and in particular as a part of, a high power (HP) pulsed power supply for plasma processing insulat.

### BACKGROUND

HP pulsed power supplies are often needed in plasma process equipment, e.g. for biasing a substrate, as disclosed in U.S. Pat. No. 10,474,184 B2, e.g.. For such a plasma process equipment, often one or more power supplies are needed, which may comprise such aforementioned electronic device. Such a power supply and such an electronic device is known from EP 4 235 738 A1, e.g., which is hereby incorporated by reference in its entirety.

In the present disclosure, high power (HP) shall mean 2 kW or more, especially 10 kW or more, of power during at least some of the pulse-on-times. High voltage (HV) shall mean voltages of 1 kV or more, especially 5 kV and more, in particular 10 kV or more, during at least some of the pulse-on-times. Pulsed power supply shall mean a power supply with a pulsing frequency being in the range of 50 Hz up to 800 kHz.

In such a HP, HV pulsed power supply the following challenges arise: For several reasons of a wanted behavior of the plasma process, the power supply should often be arranged as near as possible to the plasma process. Otherwise too much energy losses occur in the feed cable, and the feed cable costs arise. Further the voltage and/or the current rise slope could be negatively affected, e.g., due to dielectric losses within the cable. Because there is only little space available nearby the plasma chamber, the overall dimensions for such a power supply are very limited. To keep the dimensions as small as possible, electronical parts must be packed close together in the power supply. However, these small dimension requirements are contradictory to the high insulation requirements caused by the high voltages and to the low capacitance requirements in the power supply due to the high rising times of voltage and current.

The ‘electrical insulating heat transfer liquid’ should be electrically non-conducting in a reliable way. The insulating characteristics should be better than air. With ‘air’ is meant all kinds of air around in a typical environment of such an electronic device during manufacture, maintenance, tests and/or use. With such an electrically insulating liquid, lower creepage distances and/or lower discharge distances are possible than they are when air is used for insulation.

Possible liquids that may be used for cooling are disclosed in WO 2021/008949 A1, e.g., where there are described fluorinated liquids which are very effective heat transfer liquids.

It was found however that in such power supplies with direct contact cooling with said described liquids it comes to unforeseeable and random failures. Those failures where the point of research and investigation.

### SUMMARY

In an embodiment, the present disclosure provides an electronic device for a high power, high voltage pulsed power supply for plasma processing for biasing a substrate in a plasma process, the electronic device comprising a plurality of electrical components configured to generate heat when the device is in use and a container. At least a part of the plurality of electrical components are placed in the container. The electronic device further comprises an electrically insulating heat transfer liquid, filled within the container and having direct contact to the plurality of electrical components and configured to transport heat away from the plurality of electrical components. The electrically insulating heat transfer liquid is enclosed in a hermetical closed volume, the hermetical closed volume being arranged at least partly inside the container and kept in a predetermined regulated pressure range.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1A illustrates an embodiment of an electronic device;

FIG. 1B illustrates an embodiment of an electronic device;

FIG. 1C illustrates an embodiment of an electronic device;

FIG. 2 illustrates a chart showing the trend of a pressure inside a container with cooling liquid and a gas above a gas volume and the trend of a temperature of the cooling liquid over an elapsed time;

FIG. 3 illustrates a perspective partially sectioned representation of a conventional degassing unit in schematic representation used according to the present disclosure;

FIG. 4 illustrates an embodiment of an electronic device;

FIG. 5 illustrates an embodiment of an electronic device;

FIG. 6 illustrates an embodiment of an electronic device;

FIG. 7 illustrates an embodiment of a series circuit to be connected to a high voltage; and

FIG. 8 illustrates a plasma processing system with a plasma chamber.

### DETAILED DESCRIPTION

In an embodiment, the present disclosure provides an improved electronic device and an improved method of cooling an electronic device reducing the problems mentioned above. In particular, an improved electronic device that is suitable with the high power (HP) and high voltage (HV) pulsed power supply for plasma processing, is disclosed. The overall dimensions should be kept as small as possible, however without any drawbacks to reliability.

Also, a method of cooling such a device shall be disclosed.

In an aspect, an electronic device comprising a plurality of electrical components generating heat for, and in particular as a part of, a high power (HP) pulsed power supply for plasma processing is provided. The electronic device comprises:
a container, wherein said plurality of electrical components are placed,
an electrical insulating heat transfer liquid, filled within said container and having direct contact to the electrical components to transport heat away from those electrical components.

In an aspect said electrically insulating heat transfer liquid is enclosed in a hermetically closed volume, this hermetically closed volume is arranged at least partly inside the container and kept in a predetermined pressure range. This pressure range should be regulated. With a pressure range is meant a range of pressure values, such as e.g., from 2 bar to 3 bar.

In an aspect the container comprises:
a first volume filled with gas, and
a second volume filled with the electrically insulating heat transfer liquid without a separating part between the first and the second volume.

No membrane between first volume and the second volume is needed here. This is possible especially when the electrically insulating heat transfer liquid has a solubility of the gas in the first volume high enough to compensate for the volume change of the second volume with the temperature in a predefined temperature range which is the range of temperature during use of the device. In this way, the pressure rise in the container is limited.

In an aspect the container comprises:
a first volume filled with gas, and
a second volume filled with the electrically insulating heat transfer liquid, and
a membrane separating the first volume from the second volume.

In an aspect the membrane is permeable for gas in the direction from the second volume to the first volume but not in the opposite direction.

In an aspect the device comprises a pressure control, in particular a gas pressure control, to control the pressure in one or more of the following volumes:
the first volume,
the second volume, and
the hermetical closed volume.

The electrically insulating heat transfer liquid can enhance the electrical insulation between these electrical components in comparison to the electrical insulation of air.

In an aspect, above-mentioned advantages are achieved by an electrically insulating heat transfer liquid being enclosed in the container so that it has no contact with extraneous gas outside the container in operation of the electronic device, and the electrically insulating heat transfer liquid has been degassed before the start of operation.

With being ‘degassed before the start of operation’ is meant the removal of dissolved gases from the liquid. There are numerous methods for removing dissolved gases from liquids, such as pressure reduction, thermal regulation, membrane degasification, ultrasonic degassing, sparging by inert gas, addition of reductant, etc.. So, the liquid is degassed, when such a removal of dissolved gases from the liquid has intentionally taken place before the start of operation of the electronic device. This can be during production of the electronic device and/or directly before one or every start of operation.

It was found that the unforeseeable and random failures had a reason in the formation of bubbles in the liquid when the liquid heats up during operation of the electronic device. With a decrease of this bubble formation, the frequency of occurrence of such failures could be reduced. So, numerous attempts where made to reduce this formation of bubbles. One successful attempt was the degassing of the liquid and the prevention of solving of new gas during delivery, installation and/or operation.

In an aspect the degassing of said liquid is done while manufacturing the electronic device before delivery and before use of it. So, the manufacturer has full control of the degassing process and can control the condition of the device before delivery and installation. Different conditions for different applications or environments such as ambient temperature are possible to save costs in production.

In an aspect the electronic device is configured so that the degassing of the liquid can be done during maintenance and/or use of the electronic device. For such a purpose an inlet and outlet for the liquid can be attached to the container. These connections can be closable and sealable, so no gas or air from outside can come into the container during the degassing procedure.

In an aspect the electronic device comprises a degassing unit for removing gas from said liquid. With such a degassing unit connected to the container, the degassing can take place also during operation. This might be an extra benefit in process areas where the requirements on reliability of the electronic device are very high or the temperature and/or voltages between the components are very high.

In an aspect said degassing unit comprises a housing having a liquid inlet, a liquid outlet, at least one porous membrane, and at least one gas outlet. Such a degassing unit could be helpful in degasification during operation and/or maintenance.

In an aspect said degassing unit comprises a membrane including a plurality of pores for removing gas from said liquid. Such a degassing unit could be helpful in degasification during operation and/or maintenance and/or manufacture.

In an aspect said degassing unit comprises a low pressure, in particular a vacuum source connected to said at least one gas outlet. With such a degassing unit gas could be removed in a very efficient way.

In an aspect said degassing unit comprises a hollow fiber membrane array comprising a plurality of hollow fiber membranes arranged coaxially within a cartridge, a distribution tube, and a collecting tube between which a baffle is arranged for diverting liquid. With such a degassing unit gas could be removed in a very efficient way.

In an aspect the electronic device comprises a liquid guiding equipment, configured to guide the electrically insulating heat transfer liquid along at least a part of the plurality of electrical components in parallel, so that said part of the plurality of electrical components are cooled with the same temperature.

This has the big advantage in such an electronic device that electrical deviations in said part of the plurality of electrical components resulting from temperature differences between said components could be reduced. This leads to a much more stable electronic device.

There could be different solutions of liquid guiding equipment, like tubes, pumps, ventilators and so on. The important thing is that those solutions are able to guide the liquid in parallel across those electrical components to cool them with the same temperature.

In an aspect the electronic device is configured in that
a. the plurality of electrical components comprises semiconductor components, in particular transistors and/or diodes, connected in a series circuit, this series circuit configured to be connected to a high voltage ≥1 kV when in operation, where
b. the semiconductor components, in particular transistors and/or diodes, in the series circuit are connected in such a way that, in operation, the high voltage is divided between at least a part of said semiconductor components, and
c. the electronic device comprises a liquid guiding equipment, configured to guide the electrically insulating heat transfer liquid along at least a part of those semiconductor components in parallel, so that those semiconductor components are cooled with the same temperature.

It has been found that in such an electronic device, in particular in an aforementioned high power, high voltage pulsed power supply the need of a series connection of several switching elements exists. This switching element must switch so fast for the pulsed power supply that only semiconductor components are a possible solution. Transistors operated in a switch-mode, are a good possibility for those semiconductor components.

But such transistors are limited in maximum voltage across their connections and are often not suitable for voltages ≥1 kV. One solution is to connect those semiconductor components, in particular transistors, in such a way that, in operation, the high voltage is divided between at least a part of said semiconductor components. But this does only work, when that circuit is balanced good enough, so that the voltage at any of those semiconductor components does not rise above the limited value of that semiconductor component. Such a balancing is a difficult topic in design. Even small deviations could lead to an unbalance which is perhaps at the beginning small but increases with self-enhancing feedback. It was found that even the cooling equipment has an influence on the balancing. After research, it was recognized that the cooling of the components in a parallel way, with the approach to cool the components with the same temperature, has an improving influence of the overall balancing of those components.

So, it was decided to find a structure, which comprises a liquid guiding equipment, configured to guide the electrically insulating heat transfer liquid along at least a part of those semiconductor components in parallel, so that these semiconductor components are cooled with the same temperature.

As mentioned before, there could be different solutions of liquid guiding equipment, like tubes, pumps, ventilators and so on. The important thing is that those solutions are able to guide the liquid in parallel across those electrical components to cool them with the same temperature.

In an aspect the liquid guiding equipment comprises several culverts in a PCB in a predetermined distance from said semiconductor components which are placed on the PCB in a way to be cooled with the same temperature.

With PCB is meant a printed circuit board on which the electrical components can be placed and connected or similar carrier for the electrical components.

In an aspect, said transistors are operated as switching transistors to switch the pulses for the high voltage (HV) pulsed power supply. Examples and functionality are described in more detail in EP 4 235 738 A1, e.g..

In an aspect the liquid guiding equipment is made of a volume with a first pressure on one side of a PCB or carrier for electrical components and a volume with a second pressure on the other side of a PCB or carrier for electrical components and the PCB or carrier for electrical components comprises holes as culverts to guide the liquid in parallel.

In an aspect the device comprises components having contact with said liquid and being configured for moving, in particular fan wings or pump rotors, where at least some of those components are made from metal or other conductive materials or are coated by a layer of conductive material, in particular titanium nitrate.

In an aspect the device comprises a fluctuation generator configured for moving the liquid around said container for transferring heat from said electrical components.

In an aspect at least some of said electrical components are arranged so that electrical potentials of said electrical components support natural convection acting as the fluctuation generator.

In an aspect said fluctuation generator comprises a stirrer or a pump.

In an aspect said liquid is configured as a liquid filled into said container, and in that said container comprises a first volume above a liquid level of said liquid.

Moreover, with respect to the method, an embodiment of the present disclosure provides a method of cooling an electronic device, in particular a HP pulsed power supply for biasing a substrate in a plasma process, said method comprising the steps of:
providing a container,
arranging electrical components generating heat when used within said container,
filling an electrical insulating heat transfer liquid into said container,
keep the electrically insulating heat transfer liquid enclosed in a hermetical closed volume, this hermetical closed volume is arranged at least partly inside the container, and
keep the electrically insulating heat transfer liquid in a predetermined regulated pressure range.

It was found that some failures may be caused by gas bubbles in the liquid which develop during heat up of the liquid. So, it was found that the proposed usage of such insulating liquids in a gas/liquid equilibrium as proposed by WO 2021/008949 A1 can affect the usage of such a power supply adversely.

Embodiments of the present disclosure solve the problem to build a high HP, HV pulsed power supply for biasing a substrate in a plasma process. It works highly reliable with the plasma process.

According to an embodiment of the present disclosure, any insulating components having contact with the liquid and being configured for moving, such as fan wings or pump rotors, are made from metal or other conductive materials, or are coated by a layer of conductive material. Thereby, the amount of electrostatic discharges is reduced and thereby the efficiency of the components that come into contact with the insulating cooling liquid is enhanced by reducing electrostatic forces in the liquid.

According to an embodiment of the present disclosure, at least some of the electrical components are arranged so that electrical potentials of the electrical components support natural convection acting as a fluctuation generator. In view of this, a dedicated pump unit can be avoided or arranged in a smaller form. Since insulating liquids are sensitive to high gradient of electric field and can be accelerated using strong electric fields, this phenomenon can be used for moving the liquid. Usually, liquids are accelerated from the negative potential of an electric field in a direction to the positive potential. This phenomenon can be used to obtain a natural convection. To obtain natural convection, preferably the direction of electric potentials should be designed properly. Thus, mechanical pumps, fans or stirrers can be either fully avoided or the effectiveness of such devices can be enhanced by also using natural convection.

According to an embodiment of the present disclosure, the fluctuation generator comprises a stirrer or a pump. In view of this, a highly effective gas removal can be obtained.

According to an embodiment of the present disclosure, the liquid is configured as a liquid filled into the container, and the container comprises a gas volume above a liquid level of the liquid. It was found that gas solubility of cooling liquids depends on the pressure.

Since liquids expand with rising temperature, some extra empty volume should be provided to allow for the volume expansion of the cooling liquid. If the pressure increases, also the gas solubility increases. Thus, more gas is dissolved with rising pressure. Consequently, the pressure decreases and stabilizes on the level where the gas solubility is highest for a given pressure. So, the total volume of the container of the cooling liquid and the gas can be kept as small as possible.

According to an embodiment of the present disclosure, the degassing unit comprises a membrane including a plurality of pores for removing gas from the liquid. Using a membrane is very effective in removing gas from a flowing liquid. The pores are usually micropores small enough so that only gas and no liquid is removed.

According to an embodiment of the present disclosure, the effectiveness of the gas removal can be further enhanced by using a vacuum source that is connected to the at least one gas outlet.

According to an embodiment of the present disclosure, the degassing unit comprises a hollow fiber membrane array comprising a plurality of hollow fiber membranes arranged coaxially within a cartridge, a distribution tube and a collecting tube between which a baffle is arranged for diverting liquid.

Such a degassing unit is sold under the trademark “Liqui-Cel” by 3M. Such a degassing unit is dedicated for removing gases from water. According to the present disclosure such a commercial degassing unit is used for removing gas from an electrical insulating heat transfer liquid.

According to an embodiment of a method of the present disclosure, the liquid is circulated by natural convection, preferably assisted by electrical fields generated by at least some of the electrical components.

According to an embodiment of the method, the liquid is circulated by a pump or stirrer.

According to an embodiment of the present disclosure, the gas is removed from the liquid using a porous membrane.

Moreover, the gas removal can be assisted by a vacuum to enhance effectiveness.

Also, the electrical insulating heat transfer liquid can be configured as a liquid which is filled into the container with a volume extending above a top level of the liquid.

All these measures help to improve the effectiveness of the method according to the present disclosure.

It is to be understood that the features mentioned above and to be mentioned hereinafter cannot only be used in the given combination but also in different combinations or independently from each other without departing from the scope of the present disclosure.

Further features and advantages of embodiments of the present disclosure will become apparent from reading the subsequent description of preferred embodiments in combination with the accompanying drawings.

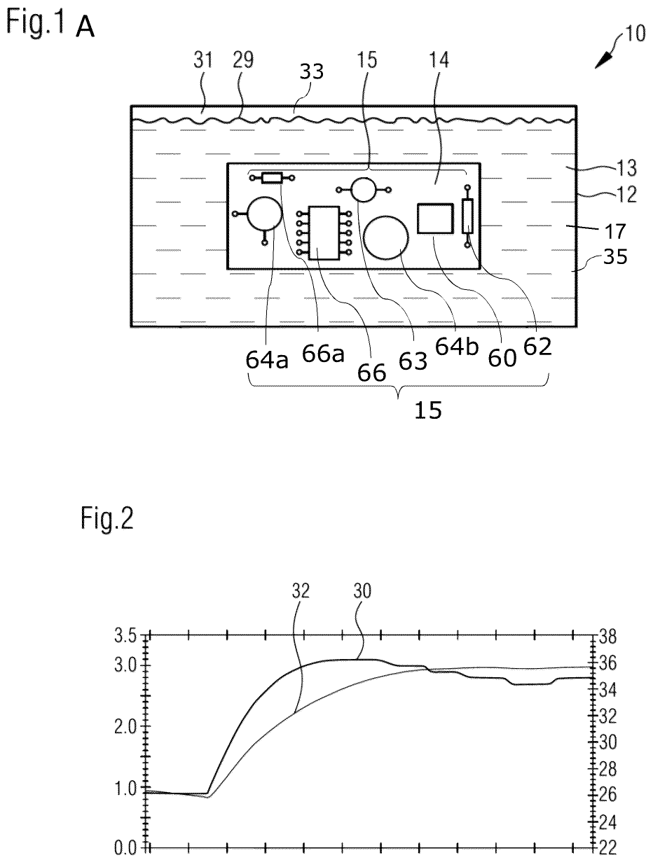

In FIG. 1A, an embodiment of an electronic device 10 according to the present disclosureis shown in a schematic representation.

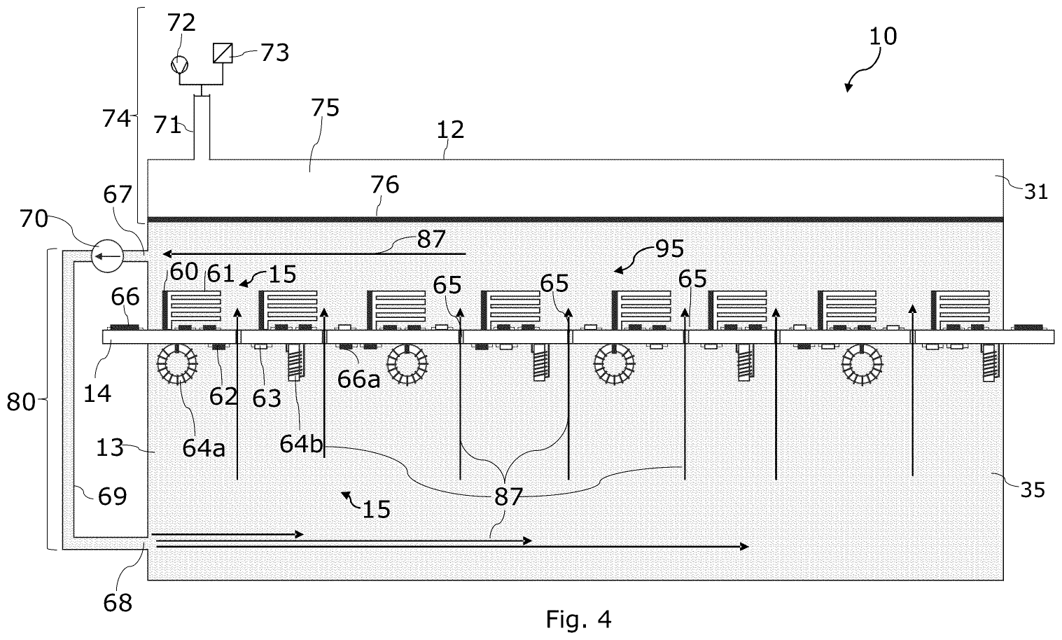

The device 10 comprises a printed circuit board (PCB) 14 or a comparable carrier of electric or electronical components 15. A variety of electric or electronical components 15 are positioned on the PCB 14. Those electric or electronical components 15 could be one or several transistors 60, diodes 66a, one or several resistors 62, one or several capacitors 63, one or several inductors and/or transformers 64a, 64b, or one or more integrated circuits 66, in particular semiconductor based, such as driver circuits for the transistors 60. They are all part of the electronic device 10. In this embodiment the whole PCB 14 and all electronical components 15 are positioned inside the container 12. This is not obligatory. It is here and in other embodiments that some of the parts 15 are outside the container 12, as it is shown later in FIG. 4-6.

A container 12 is filled with a liquid 13. The liquid 13 is configured as an insulating heat transfer liquid, e.g., such as disclosed by WO 2021/008949 A1 which is herewith fully incorporated by reference in its entirety.

The electronic device 10 can be any kind of electronic device that requires a high packaging density and requires direct liquid cooling. In particular, the device 10 can be a HP, HV pulsed power supply, in particular for biasing a substrate in a plasma process, such as known from EP 4 235 738 A1.

The electronic device 10 can be a part of a HP, HV pulsed power supply, in particular for biasing a substrate in a plasma process, in particular that part of such a power supply which needs cooling and insulation the most, such as: switching transistors, HV transformers, diodes, and damping circuits comprising inductivities and/or resistors, e.g..

The container 12 can be hermetically closed, so, no gas or liquid can leave. Gas solubility of cooling liquids can be controlled by the pressure of the liquid 13. The liquid extends with rising temperature. Thus, some extra volume 31 filled with a compressible medium such as gas above the top level 29 of the liquid 13 is required to allow the increase of second volume 35 of the liquid 13.

The electrically insulating heat transfer liquid 13 is enclosed in a hermetical closed volume 17, this hermetical closed volume 17 is arranged at least partly inside the container 12 and kept in a predetermined regulated pressure range.

If the ratio of volume of the liquid 13 and the first volume 31 of the compressible medium and the pressure at a predefined temperature is chosen in a preferred way, then the following happens: If the pressure increases, also the gas solubility increases. Therefore, more gas is dissolved by the liquid 13. Consequently, the pressure in the container decreases and stabilizes on the level where the gas solubility is highest for the present pressure.

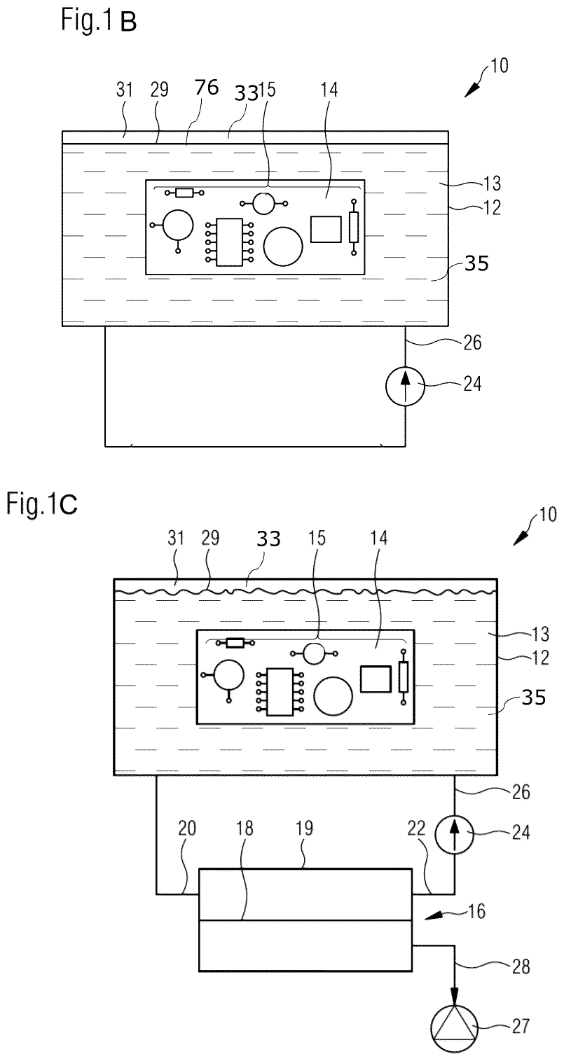

In FIG. 2, the trend of the pressure inside the container 12 with the cooling liquid 13 in the gas volume 31 on top is shown by pressure line 30, and the trend of the temperature of the cooling liquid over the time is shown by temperature line 32. Both lines 30, 32 are lines over time, so the horizontal axis is a time axis. On the right axis a scale for the values of temperature is shown in °C. On the left axis a scale of values of differential pressure is shown.

The phenomenon can be explained in the following with the help of the graph of FIG. 2: A cooling liquid 13 with a high solubility of gas can be used to reduce the container 12 volume expansion and to compensate for the volume change with the temperature. On the other hand, the volume change of the container 12 with the cooling liquid 13 and the gas shall be kept as small as possible to avoid a thermal extension of the liquid 13.

FIG. 1B shows a further embodiment of an electronic device 10. In comparison to the device 10 in FIG. 1A, a fluctuation generator 24, especially a pump is connected to the container 12. From the fluctuation generator 24 the liquid is fed back into the container 12 through a liquid line 26.

In comparison to the device 10 in FIG. 1A there is a membrane 76 between the first volume 31 and the second volume 35. This is here not obligatory; it is just shown here to demonstrate the combination possibilities of the features mentioned above.

FIG. 1C shows a further embodiment of an electronic device 10. In comparison to the device 10 in FIG. 1A, a fluctuation generator 24, and a degassing unit 16 is used for removing gas from the liquid 13 in pouring coolant over the device. In the shown device, the degassing unit 16 is arranged externally for high effectiveness and easy access. After degassing liquid 13, the degassing unit 16 can be disconnected as shown in FIGS. 1A, 1B or remains inactive.

The degassing unit 16 comprises a housing 19 within which a porous membrane 18 is arranged. Liquid 13 from the container 12 is drawn to an inlet port 20 of the degassing unit and exerts through an outlet port forced by a fluctuation generator 24, especially a pump. By the porous membrane 18 gas is removed and exerts through a gas outlet port. The gas removal is usually assisted by an external vacuum source 27.

Container 12 is filled with liquid 13 so that a small volume of gas 31 remains above the liquid. The element separating the gas from the liquid is membrane 76.

The membrane 76 is used to separate the coolant from the gas and prevents gas 31 from entering the degassed liquid 13. Such a design leads to a highly effective gas removal from the liquid 13.

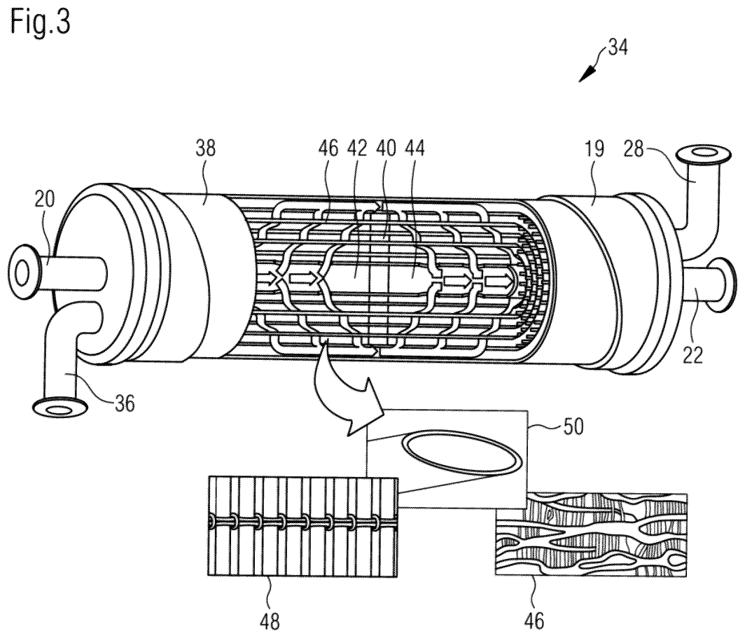

In FIG. 3, a suitable highly effective degassing unit is shown that is marketed by 3M under the trademark “Liqui-CEL” and designated in total with reference numeral 34. This degassing unit is dedicated for removing gases from water, but according to the present disclosure, is used for removing gases from the electrically insulating heat transfer liquid 13.

In the following description of FIG. 3, the same reference numerals as before are used for similar parts.

The degassing unit 34 comprises a housing 19 within which a cartridge 38 is included. At a first end of the housing 19 there is provided a liquid inlet port 20; at the second end there is provided an outlet port 22.

At the first end there is further arranged a gas/vacuum port 36 and at the second end there is arranged a gas outlet port 28. From the inlet port 20, the liquid travels through a central distribution tube 42 and is distributed in radial direction to enter into a hollow fiber membrane array 48 consisting of a plurality of hollow fiber membranes 46 that are arranged coaxially within the cartridge 38.

There is a central baffle 40 for deflection to the outside so as to improve the effectiveness. On the other side of the baffle 40, there is a central collection tube 44 for collecting the liquid after the gas removal that exerts the degassing unit 34 through the outlet port 22.

A portion of a hollow fiber membrane is shown enlarged and depicted by 46. An enlarged micropore within the membrane 46 is shown by reference numeral 50. The fiber membrane array is shown enlarged by the cutout 48.

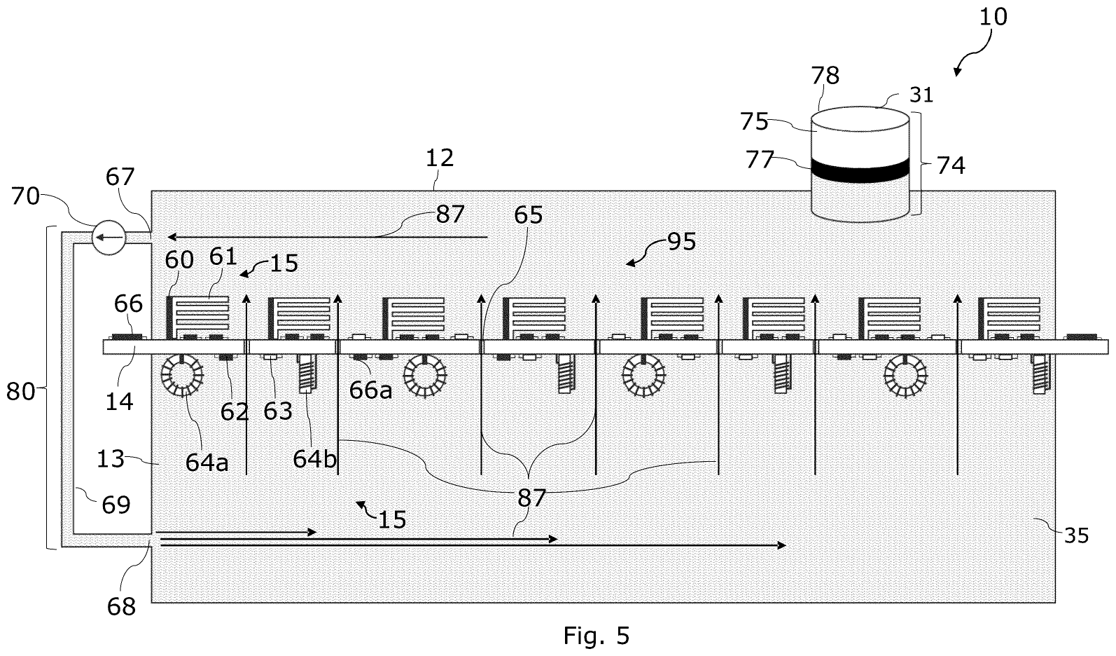

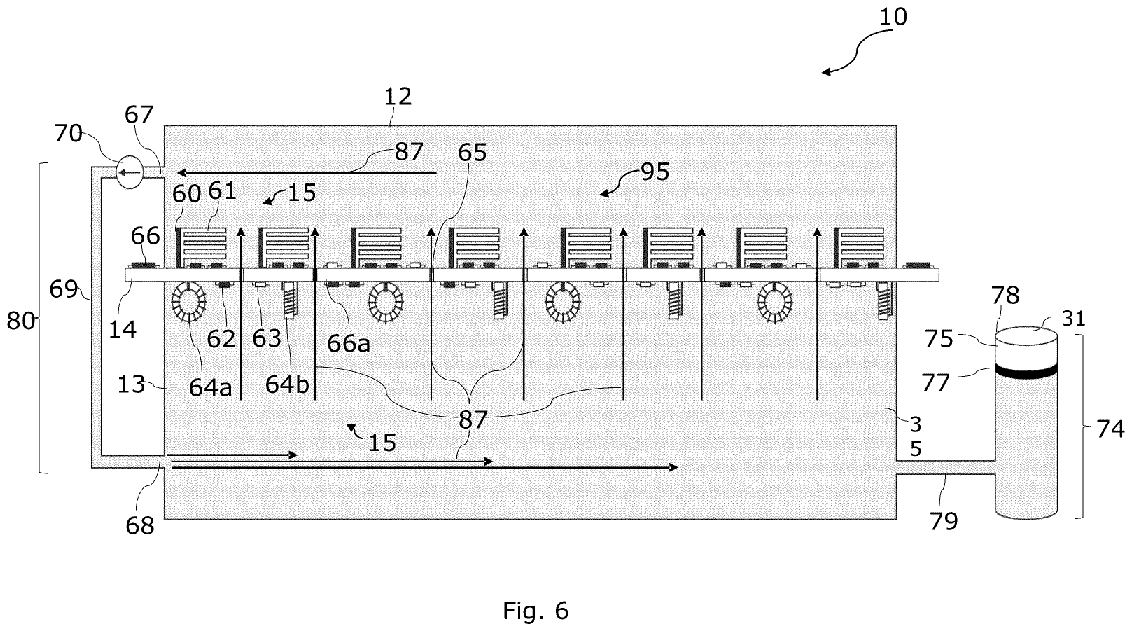

FIG. 4, FIG. 5, and FIG. 6 show three different embodiments of an electronic device 10. The electronic device 10 comprises a container 12. This container 12 comprises a heat transfer liquid 13, a PCB 14, a circulating device 80, and a pneumatic system 74.

The container 12 is filled with heat transfer liquid 13. The PCB 14 is arranged in the container 12 and surrounded by the heat transfer liquid 13. Further, the PCB 14 is led out of the container 12 on two sides.

The PCB 14 is equipped with various components. These components include transistors 60, heat sinks 61, resistors 62, capacitances 63, inductors 64a, 64b, diodes 66a, and drivers 66. The drivers 66 of the PCB 14 could be arranged outside the container 12 on the PCB 14. In this way they are thus not surrounded by the heat transfer liquid 13. The remaining components are arranged inside the container 12 on the PCB 14 and are thus surrounded by the heat transfer liquid 13. The inductors 64a, 64b are shown in two different embodiments. The heat sinks 61 are each arranged on the transistors 60 and have a plurality of pins. The PCB 14 further comprises several culverts 65. These culverts 65 are designed to allow the heat transfer liquid 13 to flow through. As a result, the heat transfer liquid 13 can flow through the PCB 14, so that above and below the PCB 14 is the same heat transfer liquid 13. For reasons of clarity, only one of the different components are provided with a reference mark. However, the remaining components can also be assigned via the same appearance of the same components.

The electronic device 10 comprises a liquid guiding equipment 95, configured to guide the electrically insulating heat transfer liquid 13 along at least a part of the plurality of electrical components 15, so that said part of the plurality of electrical components 15 are cooled with the same temperature.

As mentioned before, there could be different solutions of liquid guiding equipment 95, like tubes, pumps, ventilators and so on. The important thing is that those solutions are able to guide the liquid in parallel across those electrical components to cool them with the same temperature.

One solution is the liquid guiding equipment is made of a volume with a first pressure on one side of a PCB 14 and a volume with a second pressure on the other side of a PCB 14 and the PCB comprises holes as culverts 65 to guide the liquid in parallel.

The components described and illustrated here are exemplary for the assembly of PCB 14. The PCB 14 can also be equipped with other components, such as diodes 66a.

The circulating device 80 of the container 12 comprises a heat transfer liquid outlet 67, a heat transfer liquid inlet 68, a heat transfer liquid pump 70 and a heat transfer liquid conduit 69. When the heat transfer liquid 13 heats up, the heated heat transfer liquid rises inside the container 12 upwards. Via the heat transfer liquid outlet 67, the heat transfer liquid 13 that has risen upwards can then reach the circulating device 80, in which it can get back into the lower area of the container 12 through the heat transfer liquid pump 70, the heat transfer liquid conduit 69 and the heat transfer liquid inlet 68. Within the circulating device 80, the heat transfer liquid 13 can be cooled down by other devices. Overall, the circulating device 80 thus ensures circulation of the heat transfer liquid 13 within the container 12.

As shown with the arrows 87 the heat transfer liquid 13 flows through the culverts 65 to cool several components also the transistors 60 in parallel, so that they are cooled with the same temperature.

As the heat transfer liquid 13 heats up, it expands and the pressure in the container 12 thus increases. The container 12 has a pneumatic system 74 to counteract this pressure increase. The purpose of this pneumatic system 74 is to regulate the pressure within the container 12.

For this purpose, the pneumatic system 74 in FIG. 4 comprises a membrane 76, a gas 75, a pumping device 72 and a gas pressure control 73. The membrane 76 has an elastic material and is arranged above the PCB 14 in container 12. The membrane 76 is impermeable to the heat transfer liquid 13. For gas 75, the membrane 76 can be permeable from one side, namely from bottom to top. The gas 75 of the pneumatic system 74 is located in container 12 above the membrane 76. Due to the one-sided gas permeability of the membrane 76, unwanted gas in the heat transfer liquid 13 can pass through the membrane 76 out of the heat transfer liquid 13. As a result, the heat transfer liquid 13 can be less influenced in its function.

When the heat transfer liquid 13 expands, the membrane 76 is pushed upwards and with no change in the volume of the gas 75 in the container 12, the pressure in the container 12 increases. However, via the pumping device 72 and the gas pressure control 73, the volume of the gas 75 in container 12 can be increased or reduced. The pumping device 72 and gas pressure control 73 are connected to the container 12 via the gas outlet 71.

Overall, the pneumatic system 74 can therefore increase or reduce the pressure in container 12 by increasing or reducing the volume of the gas 75 in container 12.

In FIG. 5 and FIG. 6, the pneumatic system 74 has a cylinder 78, a piston 77, gas 75, a pumping device 72, and a gas pressure control 73.

Basically, the pneumatic system 74 has here the same function and also functionality as the pneumatic system 74 from FIG. 4.

The only difference is that the pneumatic system 74 is designed in the form of a cylinder 78. The gas 75 of the pneumatic system 74 via which the pressure in the container 12 is regulated, is arranged within the cylinder 78, above the piston 77 and is not located in the container 12. The piston 77 assumes the function of the membrane 76 and can be moved up and down via the volume of gas 75 located in the cylinder 78 in order to change the pressure in the container 12. The pumping device 72 and the gas pressure control 73 can be located at the top of the cylinder 78.

In FIG. 5, this cylinder 78 is introduced into the container 12. Thus, the heat transfer liquid 13 of the container 12 can enter the cylinder 78 via an open underside of the cylinder 78.

In FIG. 6, the cylinder 78 is arranged outside the container 12 and connected via a cylinder conduit 79 to the container 12. Via the cylinder conduit 79, the heat transfer liquid 13 of the container 12 can enter the cylinder 78. The cylinders 78 can have the same material as the container 12.

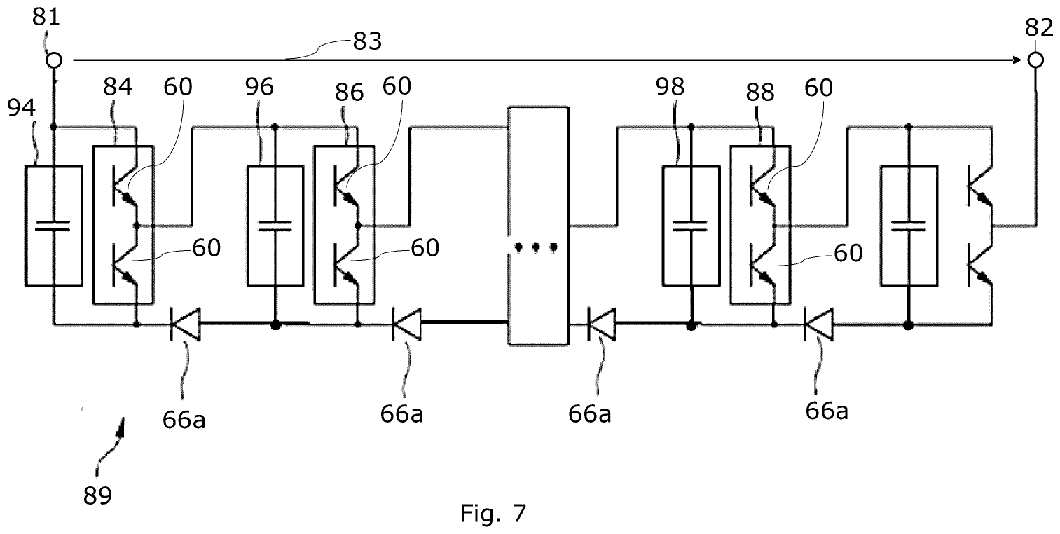

FIG. 7 shows an embodiment of a series circuit 89 configured to be connected to a high voltage 83, HV ≥1 kV when in operation. This HV 83 between the connection points 81 and 82 can be established by a plurality of low-power generators (LP-generators) 94, 96, 98, connected in series.

The series circuit 89 comprise semiconductor components 84, in particular transistors 60 and/or diodes 66a, each connected in series.

Further details and functions of such a circuit are explained in EP 4 235 738 A1. The embodiment of a series circuit 89 shown in FIG. 7 is only one of several possible embodiments. Some further embodiments are described in EP 4 235 738 A1, e.g..

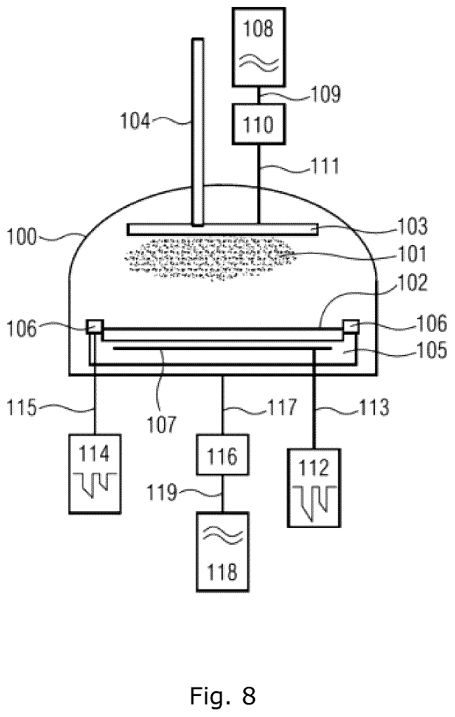

FIG. 8 shows a plasma processing system with a plasma chamber 100 in which a plasma 101 is established in a plasma space. Such or similar systems are shown and described also in EP 4 235 738 A1, e.g.. For such or a similar system the device 10 of this description is designed. In the plasma chamber an upper electrode 103 can be positioned. A gas inlet and/or outlet, in particular a gas supply pipe 104 can be placed from the outside to the inside of the plasma chamber 100, in particular connected to the electrode 103. A substrate 102, in particular a semiconductor wafer can be placed on a support 105 which comprises a substrate holder inside the plasma chamber 100. In use the substrate 102 can be processed by the plasma 101, e.g., in a process of etching, ashing, or deposition in particular with atomic layered deposition. Etching process can be an extremely high challenge, for instance when the ratio between etched hole diameter and hole length is extremely low, <1/100, e.g., as it is in deep etching often necessary. An electric conductive electrode 106 can be placed in the plasma chamber 100, in particular nearby the substrate 102, for example around the substrate 102. This electric conductive electrode 106 can be an edge ring which can be also called focus ring. This electric conductive electrode 106 can be connected to a first power supply 114 via a first connection line 115. The first power supply 114 can be a DC pulsed power supply, where in particular the pulses can be of different length, different amplitude and shaped as described in U.S. Pat. No. 10,474,184 B2, FIG. 2 e.g..

With the control of the first power supply 114 the electric conductive electrode 106 can be used additionally or alternatively as an ion energy and/or ion acceleration direction control as also described in U.S. Pat. No. 10,474,184 B2. A first radio-frequency (RF) power supply 118 can be electrically connected to the support 105 via a first power feeding rod 119 and a first matching unit 116 and a first connection unit 117. A second radio-frequency (RF) power supply 108 can be electrically connected to the upper electrode 103 via a second power feeding rod 109 and a second matching unit 110 and a second connection unit 111. An electrode 107 can be positioned in or nearby the support 105 and is electrically connected to a second power supply 112 via a second connection line 113. The second power supply 112 can be a DC pulsed power supply, where in particular the pulses can be of different length, different amplitude and shaped as described in U.S. Pat. No. 10,474,184 B2, FIG. 2, e.g.. The substrate 102 can be fixed at the support 105 via the electrode 107 which can work as an electrostatic chuck. With the control of the second power supply 112, the electrode 107 can be used additionally or alternatively as an ion energy and/or ion acceleration direction control as described in U.S. Pat. No. 10,474,184 B2.

Some plasma treatment applications, such as etching or layer deposition, demand a high voltage (HV), high frequency (HF), rectangular, asymmetrical, pulsed voltage supply. Often the voltage values significantly exceed the voltage handling possibilities of individual semiconductor switches, especially when high frequency operation is required.

Some plasma applications require not only pulsing, but pulse-to-pulse amplitude variation. Some plasma applications require the source to deliver high peak currents in order to obtain short voltage transition times. Most plasma applications present a load, which contains a capacitive component. Significant power loss is related to the pulse-by-pulse charging and discharging process of this load capacitance. Some plasma applications require pulse shaping as described in U.S. Pat. No. 10,474,184 B2, FIG. 2, e.g..

All described power supplies 104, 112, 114, 118 can comprise an electronic device 10 as described in the present disclosure.

For the HV, a series connection of such switches is one solution. Series connection requires voltage balancing means. These voltage balancing means are not easily realizable, especially in RF operation. Even smart changes in the series connection can follow to unbalances which are often self-enhancing and further deteriorate the system. It was found that even a cooling system which cools the series connection of switches in series and not in parallel might have such an impact.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. An electronic device for a high power, high voltage pulsed power supply for plasma processing for biasing a substrate in a plasma process, the electronic device comprising:
a plurality of electrical components configured to generate heat when the device is in use;
a container, wherein at least a part of the plurality of electrical components are placed in the container;
an electrically insulating heat transfer liquid, filled within the container and having direct contact to the plurality of electrical components and configured to transport heat away from the plurality of electrical components;
wherein the electrically insulating heat transfer liquid is enclosed in a hermetical closed volume, the hermetical closed volume being arranged at least partly inside the container and kept in a predetermined regulated pressure range.

2. The device of claim 1, wherein the container comprises:
a first volume filled with gas, and
a second volume filled with the electrically insulating heat transfer liquid without a separating part between the first and the second volume.

3. The device of claim 1, wherein the electrically insulating heat transfer liquid has a solubility of the gas in the first volume high enough to compensate for a volume change of the second volume with a temperature in a predefined temperature range which is a range of temperature during use of the device.

4. The device of claim 1, wherein the container comprises:
a first volume filled with gas, and
a second volume filled with the electrically insulating heat transfer liquid, and
a membrane separating the first volume from the second volume.

5. The device of claim 4, wherein the membrane is permeable for gas in a direction from the second volume to the first volume but not in an opposite direction.

6. The device of claim 4, wherein the device comprises a gas pressure control configured to control pressure in one or more of the following volumes:
the first volume,
the second volume, and/or
the hermetical closed volume.

7. The device of claim 1, wherein the electrically insulating heat transfer liquid is enclosed in the container so that it has no contact with extraneous gas outside the container in operation of the electronic device, and wherein the electrically insulating heat transfer liquid is degassed before a start of operation.

8. The device of claim 1, wherein the degassing of the electrically insulating heat transfer liquid is done while manufacturing the electronic device before delivery and before use and/or wherein the electronic device is configured such that the degassing of the electrically insulating heat transfer liquid is done during maintenance and/or use of the electronic device.

9. The device of claim 1, wherein the electronic device further comprises a degassing unit for removing gas from the electrically insulating heat transfer liquid.

10. The device of claim 1, wherein
the electronic device comprises a liquid guiding equipment configured to guide the electrically insulating heat transfer liquid along at least a part of the plurality of electrical components, so that the part of the plurality of electrical components are cooled with the same temperature.

11. The device of claim 1, wherein:
the plurality of electrical components comprises semiconductor components, including transistors and/or diodes, connected in a series circuit, the series circuit configured to be connected to a high voltage greater than or equal to 1 kV when in operation,
the semiconductor components in the series circuit are connected such that, in operation, the high voltage is divided between at least a part of the semiconductor components, and
the electronic device comprises a liquid guiding equipment, configured to guide the electrically insulating heat transfer liquid along at least a part of the semiconductor components in parallel, so that the semiconductor components are cooled with the same temperature.

12. The device of any of claim 11, wherein the liquid guiding equipment comprises a plurality of culverts in a printed circuit board (PCB) in a predetermined distance from the semiconductor components which are placed on the PCB so as to be cooled with the same temperature.

13. The device of claim 1, wherein the device comprises fan wings and/or pump rotors having contact with the electrically insulating heat transfer liquid and being configured to move, wherein at least some of the fan wings and/or pump rotors are made from metal or other conductive materials, or are coated by a layer of titanium nitrate.

14. The device of claim 1, wherein the electrically insulating heat transfer liquid is configured as a liquid filled into the container, and wherein the container comprises a gas volume above a liquid level of the electrically insulating heat transfer liquid.

15. A method of cooling an electronic device comprising a plurality of electrical components generating heat, the method comprising
providing a container;
arranging the plurality of electrical components within the container;
filling an electrically insulating heat transfer liquid into the container;
keeping the electrically insulating heat transfer liquid enclosed in a hermetical closed volume, the hermetical closed volume being arranged at least partly inside the container, and
keeping the electrically insulating heat transfer liquid in a predetermined regulated pressure range.
